(19) United States
(12) Patent Application Publication
(10) Pub. No.: US 2011/0058432 A1
(43) Pub. Date: Mar. 10, 2011

(54) SEMICONDUCTOR INTEGRATED CIRCUIT

(75) Inventors: Ji Yeon YANG, Gyeonggi-do (KR); Kwan Weon KIM, Gyeonggi-do (KR)

(73) Assignee: HYNIX SEMICONDUCTOR INC., Gyeonggi-do (KR)

(21) Appl. No.: 12/648,408

(22) Filed: Dec. 29, 2009

(30) Foreign Application Priority Data
Sep. 4, 2009 (KR) 10-2009-0083342

(51) Int. Cl. G11C 7/00; G11C 8/18

(52) U.S. Cl. 365/193; 365/194; 365/233.1

(57) ABSTRACT

A semiconductor integrated circuit is provided that includes a first pad, a data storage and input/output block configured to store and output data by using a data strobe signal and a clock signal inputted through the first pad, and a timing compensation unit configured to delay the clock signal to generate the data strobe signal.

### CROSS-REFERENCES TO RELATED APPLICATION

The present application claims priority under 35 U.S.C. §119(a) to Korean application number 10-2009-0083342, filed on Sep. 4, 2009, in the Korean Intellectual Property Office, which is incorporated herein by reference in its entirety as set forth in full.

### BACKGROUND

The present invention relates to a semiconductor circuit, and more particularly, to a semiconductor integrated circuit.

As illustrated in FIG. 1, a conventional semiconductor integrated circuit 10 includes a clock signal pad 11, a write data strobe signal pad 12, circuit blocks 13 and 14, and a data storage and input/output block 20.

The clock signal pad 11 is configured to receive an external clock signal CLK.

The write data strobe signal pad 12 is configured to receive an external write data strobe signal WDQS.

The write data strobe signal WDQS is a signal which provides a timing for enabling the semiconductor integrated circuit 10 to receive data to be written by a test device (not shown). The write data strobe signal WDQS is provided to the semiconductor integrated circuit 10 together with a write command by the test device. In addition to the clock signal CLK, the write data strobe signal WDQS is indispensable to the operation of the semiconductor integrated circuit 10.

The circuit block 13 may include a buffer or a delay locked loop (DLL) configured to generate signals necessary for the operation of the semiconductor integrated circuit 10 by using the clock signal CLK.

The circuit block 14 may include a buffer or a phase separator configured to generate signals necessary for the operation of the semiconductor integrated circuit 10 by using the write data strobe signal WDQS.

The data storage and input/output block 20 may include a memory cell area and a variety of circuits configured to write data to the memory cell area, or read data from the memory cell area.

It is necessary to test whether or not there is an error in the operation of the semiconductor integrated circuit 10.

A test device must provide the clock signal CLK and the write data strobe signal WDQS through separate channels in order to test the operation of the semiconductor integrated circuit.

In addition to the channels for transmitting the clock signal CLK and the write data strobe signal WDQS, additional channels for transmitting addresses and data are required.

In the test device, however, the number of channels for transmitting and receiving a variety of signals is limited. Furthermore, the clock signal CLK and the write data strobe signal WDQS are high frequency signals. Only a few channels among the channels of the test device may support high frequency signals. Therefore, there is a limitation on the number of semiconductor integrated circuits the test device can test at a time.

### SUMMARY

A semiconductor integrated circuit capable of reducing the number of channels necessary for a test operation is described herein.

In one embodiment of the present invention, a semiconductor integrated circuit includes: a first pad; a data storage and input/output block configured to store and output data by using a data strobe signal and a clock signal inputted through the first pad; and a timing compensation unit configured to delay the clock signal to generate the data strobe signal.

In another embodiment of the present invention, a semiconductor integrated circuit includes: a first pad; a data storage and input/output block configured to store and output data by using a data strobe signal and a delay locked loop (DLL) clock signal; a delay locked loop configured to generate the DLL clock signal by using a clock signal inputted through the first pad; and a timing compensation unit configured to delay the DLL clock signal to generate the data strobe signal.

In another embodiment of the present invention, a semiconductor integrated circuit includes: a first pad; a data storage and input/output block configured to store and output data by using a data strobe signal and a delay locked loop (DLL) clock signal; and a delay locked loop configured to receive a clock signal through the first pad, and generate the DLL clock signal by delaying the received clock signal through a delay line including a plurality of delay elements, wherein an output signal of a single delay element among the plurality of delay elements is generated as the data strobe signal.

### BRIEF DESCRIPTION OF THE DRAWINGS

Features, aspects, and embodiments are described in conjunction with the attached drawings, in which:

FIG. 1 is a block diagram of a conventional semiconductor integrated circuit;

FIG. 2 is a block diagram of a semiconductor integrated circuit according to one embodiment;

FIG. 3 is a block diagram of a semiconductor integrated circuit according to another embodiment; and

FIG. 4 is a block diagram of a semiconductor integrated circuit according to another embodiment.

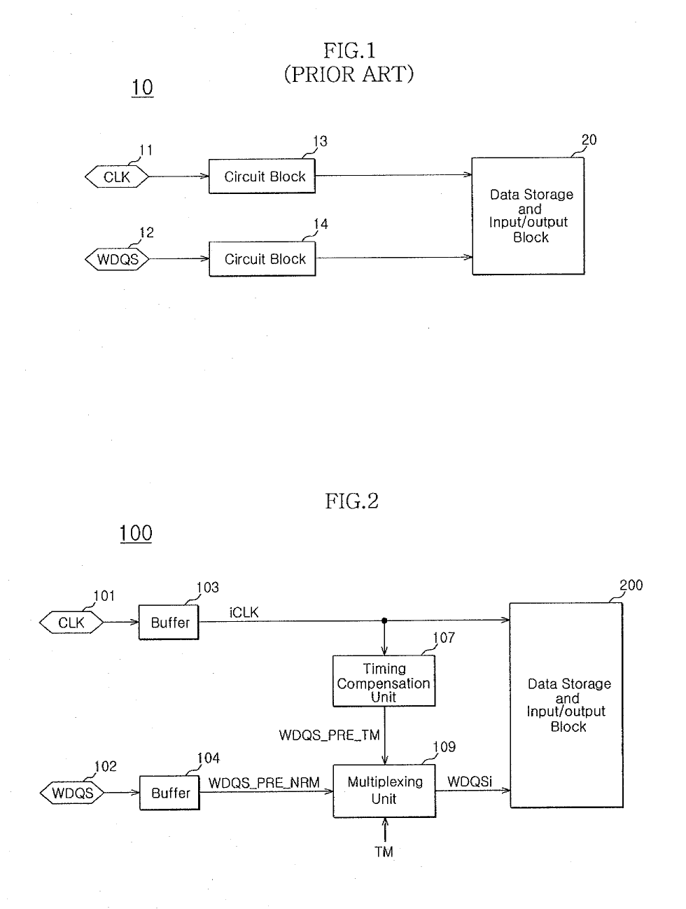

### DETAILED DESCRIPTION

Hereinafter, a semiconductor integrated circuit according to the present invention will be described below with reference to the accompanying drawings through preferred embodiments. As required, detailed embodiments of the present invention are disclosed herein. However, it is to be understood that the disclosed embodiments are merely exemplary of the invention, which may be embodied in various forms. Therefore, specific details disclosed herein are not to be interpreted as limiting, but merely as a basis for the claims and as a representative basis for teaching one skilled in the art to variously employ the present invention in virtually any appropriate manner.

In testing a semiconductor integrated circuit, a test device writes data having a predetermined pattern to the semiconductor integrated circuit, and reads the written data to monitor whether the data is written correctly or not.

The clock signal CLK is basically required for the read and write operations in the semiconductor integrated circuit, and the write data strobe signal WDQS is required as a strobe signal for reading an external data at an appropriate timing.

According to one embodiment, the signal having the same timing as the write data strobe signal WDQS may be generated using the clock signal CLK, without receiving the write data strobe signal WDQS from the test device.

First, one embodiment will be described with reference to FIG. 2.

Referring to FIG. 2, the semiconductor integrated circuit 100 according to one embodiment includes a clock signal pad 101, a write data strobe signal pad 102, buffers 103 and 104, a timing compensation unit 107, a multiplexing unit 109, and a data storage and input/output block 200.

The clock signal pad 101 is configured to receive a clock signal CLK.

The write data strobe signal pad 102 is configured to receive a write data strobe signal WDQS.

The buffer 103 is configured to buffer the clock signal CLK to generate an internal clock signal iCLK.

The buffer 104 is configured to buffer the write data strobe signal WDQS to generate a preliminary write data strobe signal WDQS_PRE_NRM for a normal mode.

The timing compensation unit 107 is configured to generate a preliminary write data strobe signal WDQS_PRE_TM for a test mode by delaying the internal clock signal iCLK by a predetermined time that can compensate a timing offset between the internal clock signal iCLK and the preliminary write data strobe signal WDQS_PRE_NRM for the normal mode.

Therefore, according to this embodiment, the timing of the preliminary write data strobe signal WDQS_PRE_TM for the test mode may be substantially synchronized with the timing of the preliminary write data strobe signal WDQS_PRE_NRM for the normal mode, for example.

The multiplexing unit 109 is configured to select one of the preliminary write data strobe signal WDQS_PRE_NRM for the normal mode and the preliminary write data strobe signal WDQS_PRE_TM for the test mode according to a test mode signal TM, and output the selected preliminary write data strobe signal as an internal write data strobe signal WDQSi. Specifically, the multiplexing unit 109 selects the preliminary write data strobe signal WDQS_PRE_TM for the test mode when the test mode signal TM is activated, selects the preliminary write data strobe signal WDQS_PRE_NRM for the normal mode when the test mode signal TM is deactivated, and outputs the selected preliminary write data strobe signal as the internal write data strobe signal WDQSi.

The data storage and input/output block 200, for example, may include a memory cell area and a variety of circuits configured to write data to the memory cell area, or read data from the memory cell area.

The operation of the semiconductor integrated circuit 100 according to one embodiment will be described below.

In the test mode, the clock signal CLK outputted from the test device is provided to the semiconductor integrated circuit 100 through the clock signal pad 101, and the test mode signal TM is activated.

In this case, the operation mode of the semiconductor integrated circuit 100, i.e., the read, write or test mode, may be set by a combination of address signals, for example. Therefore, the test device, for example, may activate the test mode signal TM by inputting the appropriately combined address signal.

The clock signal CLK is provided as the internal clock signal iCLK to the data storage and input/output block 200 through the buffer 103.

The internal clock signal iCLK is delayed by a set time through the timing compensation unit 107, and the delayed internal clock signal iCLK is provided to the multiplexing unit 109 as the preliminary write data strobe signal WDQS_PRE_TM for the test mode, which has the same timing as the preliminary write data strobe signal WDQS_PRE_NRM for the normal mode.

Since the test mode signal TM is in the activated state, the preliminary write data strobe signal WDQS_PRE_TM for the test mode is selected by the multiplexing unit 109 and provided to the data storage and input/output block 200 as the internal write data strobe signal WDQSi.

The data storage and input/output block 200 writes data provided from the test device to the memory cell area by using the internal clock signal iCLK and the internal write data strobe signal WDQSi, and outputs the written data to the test device according to is the read command of the test device.

Consequently, when testing the operation of the semiconductor integrated circuit 100 according to this embodiment, it is unnecessary to provide the write data strobe signal WDQS, and thus, the number of channels necessary for the test operation may be reduced.

Meanwhile, in the normal mode, the test mode signal TM is deactivated.

The write data strobe signal WDQS is provided as the preliminary write data strobe signal WDQS_PRE_NRM for the normal mode to the data storage and input/output block 200 through the buffer 104.

Since the test mode signal TM is in the deactivated state, the preliminary write data strobe signal WDQS_PRE_NRM for the normal mode is selected by the multiplexing unit 109 and provided to the data storage and input/output block 200 as the internal write data strobe signal WDQSi.

The data storage and input/output block 200 performs the data write operation or the data read operation by using the internal clock signal iCLK and the internal write data strobe signal WDQSi according to a write or read command of a memory controller, e.g., a central processing unit (CPU) or a graphic processing unit (GPU).

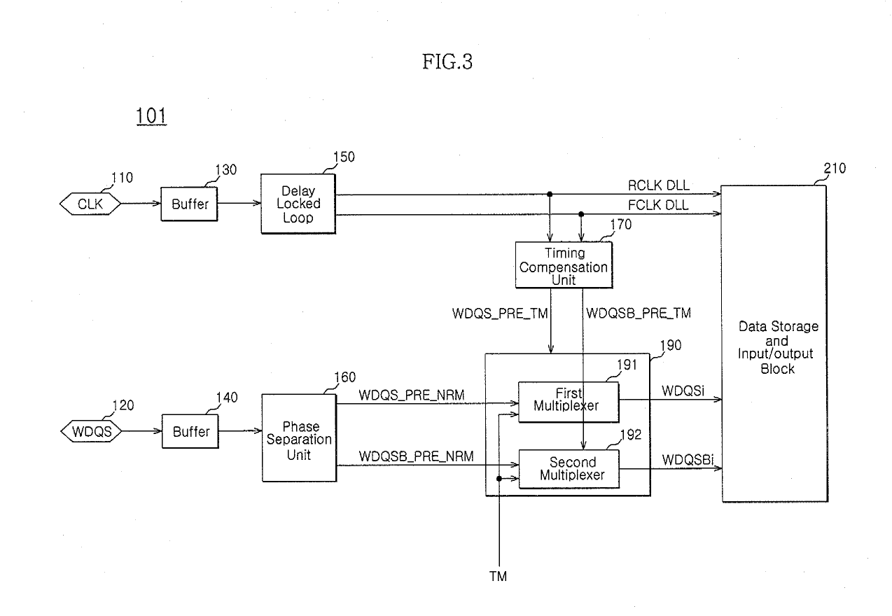

Next, another embodiment will be described with reference to FIG. 3.

Referring to FIG. 3, the semiconductor integrated circuit 101 according to another embodiment includes a clock signal pad 110, a write data strobe signal pad 120, buffers 130 and 140, a delay locked loop (DLL) 150, a phase separation unit 160, a timing compensation unit 170, a multiplexing unit 190, and a data storage and input/output block 210.

The clock signal pad 110 is configured to receive a clock signal CLK.

The write data strobe signal pad 120 is configured to receive a write data strobe signal WDQS.

The buffer 130 is configured to buffer the clock signal CLK.

The buffer 140 is configured to buffer the write data strobe signal WDQS.

The delay locked loop 150 is configured to generate DLL clock signals RCLKDLL and FCLKDLL by using the output signal of the buffer 130. The DLL clock signal RCLKDLL is a signal generated by compensating a timing offset between a rising edge of the clock signal CLK and the output data, and the DLL clock signal FCLKDLL is a signal generated by compensating a timing offset between a falling edge of the clock signal CLK and the output data.

The phase separation unit 160 is configured to separate a phase of the output signal of the buffer 140 to generate preliminary write data strobe signals WDQS_PRE_NRM and WDQSB_PRE_NRM for a normal mode.

The timing compensation unit 170 is configured to generate preliminary write data strobe signals WDQS_PRE_TM and WDQSB_PRE_TM for a test mode by delaying the DLL clock signals RCLKDLL and FCLKDLL by a set time that can compensate a timing offset between the DLL clock signals RCLKDLL and FCLKDLL and the preliminary write data strobe signals WDQS_PRE_NRM and WDQSB_PRE_NRM for the normal mode.

Therefore, according to this embodiment, the timing of the preliminary write data strobe signals WDQS_PRE_TM and WDQSB_PRE_TM for the test mode may be substantially synchronized with the timing of the preliminary write data strobe signals WDQS_PRE_NRM and WDQSB_PRE_NRM for the normal mode, for example.

The multiplexing unit 190 is configured to select one of the preliminary write data strobe signals WDQS_PRE_NRM and WDQSB_PRE_NRM for the normal mode and the preliminary write data strobe signals WDQS_PRE_TM and WDQSB_PRE_TM for the test mode according to a test mode signal TM, and output the selected preliminary write data strobe signals as internal write data strobe signals WDQSi and WDQSBi.

The multiplexing unit 190 includes a first multiplexer 191 and a second multiplexer 192.

The first multiplexer 191 selects the preliminary write data strobe signal WDQS_PRE_TM for the test mode when the test mode signal TM is activated, selects the preliminary write data strobe signal WDQS_PRE_NRM for the normal mode when the test mode signal TM is deactivated, and outputs the selected preliminary write data strobe signal as the internal write data strobe signal WDQSi.

The second multiplexer 192 selects the preliminary write data strobe signal WDQSB_PRE_TM for the test mode when the test mode signal TM is activated, selects the preliminary write data strobe signal WDQSB_PRE_NRM for the normal mode when the test mode signal TM is deactivated, and outputs the selected preliminary write data strobe signal as the internal write data strobe signal WDQSBi.

The data storage and input/output block 210, for example, may include a memory cell area and a variety of circuits configured to write data to the memory cell area, or read data from the memory cell area.

The operation of the semiconductor integrated circuit 101 according to another embodiment will be described below.

In the test mode, the clock signal CLK outputted from the test device is provided to the semiconductor integrated circuit 101 through the clock signal pad 110, and the test mode signal TM is activated.

In this case, the operation mode of the semiconductor integrated circuit 101, i.e., the read, write or test mode, may be set by a combination of address signals, for example. Therefore, the test device may activate the test mode signal TM by inputting the appropriately combined address signal, for example.

The clock signal CLK is provided through the buffer 130 to the delay locked loop 150.

The delay locked loop 150 generates the DLL clock signals RCLKDLL and FCLKDLL by using the output signal of the buffer 130, and provides the DLL clock signals RCLKDLL and FCLKDLL to the data storage and input/output block 210.

The DLL clock signals RCLKDLL and FCLKDLL are delayed by a set time through the timing compensation unit 170, and the delayed DLL clock signals RCLKDLL and FCLKDLL are provided to the multiplexing unit 190 as the preliminary write data strobe signals WDQS_PRE_TM and WDQSB_PRE_TM for the test mode which have the same timing as the preliminary write data strobe signals WDQS_PRE_NRM and WDQSB_PRE_NRM for the normal mode.

Since the test mode signal TM is in the activated state, the preliminary write data strobe signals WDQS_PRE_TM and WDQSB_PRE_TM for the test mode are selected by the multiplexing unit 190 and provided to the data storage and input/output block 210 as the internal write data strobe signals WDQSi and WDQSBi.

The data storage and input/output block 210 writes data provided from the test device to the memory area by using the internal write data strobe signals WDQSi and WDQSBi, and outputs the written data to the test device by using the DLL clock signals RCLKDLL and FCLKDLL according to the read command of the test device.

Consequently, when testing the operation of the semiconductor integrated circuit 101 according to this embodiment, it is unnecessary to provide the write data strobe signal WDQS, and thus, the number of channels necessary for the test operation may be reduced.

Meanwhile, in the normal mode, the test mode signal TM is deactivated.

The write data strobe signal WDQS is provided as the preliminary write data strobe signals WDQS_PRE_NRM and WDQSB_PRE_NRM for the normal mode to the data storage and input/output block 210 through the buffer 104 and the phase separation unit 160.

Since the test mode signal TM is in the deactivated state, the preliminary write data strobe signals WDQS_PRE_NRM and WDQSB_PRE_NRM for the normal mode are selected by the multiplexing unit 190 and provided to the data storage and input/output block 210 as the internal write data strobe signal WDQSi.

The data storage and input/output block 210 writes data provided from the memory controller to the memory cell area by using the internal write data strobe signals WDQSi and WDQSBi according to the write command of the memory controller, e.g., a CPU or a GPU, and outputs the written data to the memory controller by using the DLL clock signals RCLKDLL and FCLKDLL according to the read command of the memory controller.

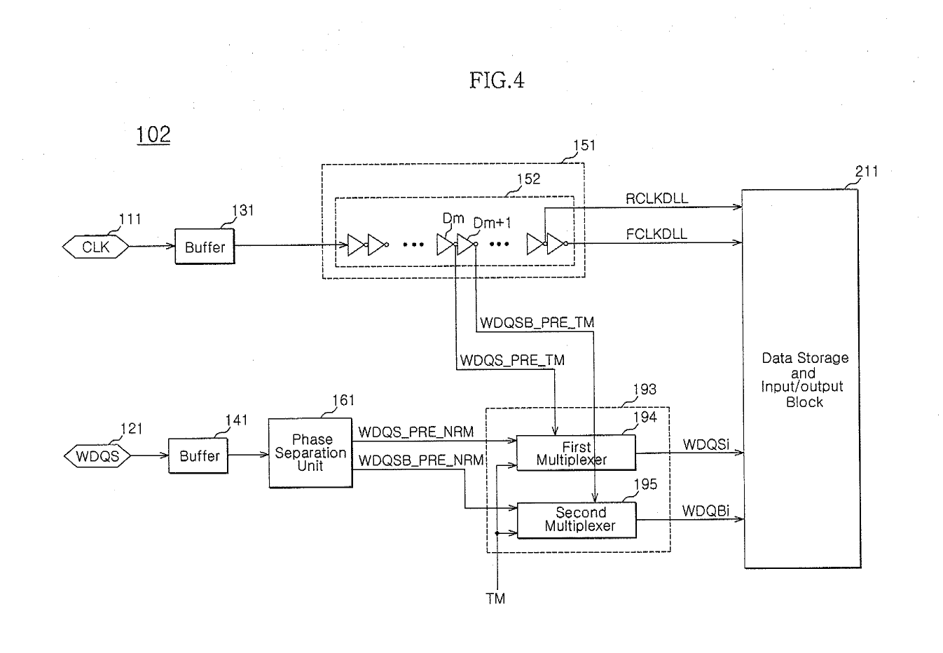

Next, another embodiment will be described with reference to FIG. 4.

Referring to FIG. 4, the semiconductor integrated circuit 102 according to another embodiment includes a clock signal pad 111, a write data strobe signal pad 121, buffers 131 and 141, a delay locked loop 151, a phase separation unit 161, a multiplexing unit 193, and a data storage and input/output block 211.

The clock signal pad 111 is configured to receive a clock signal CLK.

The write data strobe signal pad 121 is configured to receive a write data strobe signal WDQS.

The buffer 131 is configured to buffer the clock signal CLK.

The buffer 141 is configured to buffer the write data strobe signal WDQS.

The delay locked loop 151 includes a delay line 152 and is configured to receive the output signal of the buffer 131 to generate DLL clock signals RCLKDLL and FCLKDLL by using the delay line 152. The DLL clock signal RCLKDLL is a signal generated by compensating a timing offset between a rising edge of the clock signal CLK and the output data, and the DLL clock signal FCLKDLL is a signal generated by compensating a timing offset between a falling edge of the clock signal CLK and the output data.

The phase separation unit 161 is configured to separate a phase of the output signal of the buffer 141 to generate preliminary write data strobe signals WDQS_PRE_NRM and WDQSB_PRE_NRM for a normal mode.

The multiplexing unit 193 is configured to select one of the preliminary write data strobe signals WDQS_PRE_NRM and WDQSB_PRE_NRM for the normal mode and the preliminary write data strobe signals WDQS_PRE_TM and WDQSB_PRE_TM for the test mode according to a test mode signal TM, and output the selected preliminary write data strobe signals as internal write data strobe signals WDQSi and WDQSBi.

The multiplexing unit 193 includes a first multiplexer 194 and a second multiplexer 195.

The first multiplexer 194 selects the preliminary write data strobe signal WDQS_PRE_TM for the test mode when the test mode signal TM is activated, selects the preliminary write data strobe signal WDQS_PRE_NRM for the normal mode when the test mode signal TM is deactivated, and outputs the selected preliminary write data strobe signal as the internal write data strobe signal WDQSi.

The second multiplexer 195 selects the preliminary write data strobe signal WDQSB_PRE_TM for the test mode when the test mode signal TM is activated, selects the preliminary write data strobe signal WDQSB_PRE_NRM for the normal mode when the test mode signal TM is deactivated, and outputs the selected preliminary write data strobe signal as the internal write data strobe signal WDQSBi.

According to this embodiment, among a plurality of delay elements constituting the delay line 152 of the delay locked loop 151, output signals of delay elements Dm and Dm+1, which delay the output signal of the buffer 131 by a set time that can compensate a timing offset between the DLL clock signals RCLKDLL and RCLKDLL and the preliminary write data strobe signals WDQS_PRE_NRM and WDQSB_PRE_NRM for the normal mode, are used as the preliminary write data strobe signals WDQS_PRE_TM and WDQSB_PRE_TM for the test mode.

Therefore, according to this embodiment, the preliminary write data strobe signals WDQS_PRE_TM and WDQSB_PRE_TM for the test mode may, for example, be synchronized with the preliminary write strobe signals WDQS_PRE_NRM and WDQSB_PRE_NRM for the normal mode.

The data storage and input/output block 211 may include a memory cell area and a variety of circuits configured to write data to the memory cell area, or read data from the memory cell area, for example.

The operation of the semiconductor integrated circuit 102 according to another embodiment will be described below.

In the test mode, the clock signal CLK outputted from the test device is provided to the semiconductor integrated circuit 102 through the clock signal pad 111, and the test mode signal TM is activated.

In this case, the operation mode of the semiconductor integrated circuit 102, i.e., the read, write or test mode, for example, may be set by a combination of address signals. Therefore, the test device may activate the test mode signal TM by inputting the appropriately combined address signal, for example.

The clock signal CLK is provided through the buffer 131 to the delay locked loop 151.

The delay locked loop 151 generates the DLL clock signals RCLKDLL and FCLKDLL to the data storage and input/output block 211.

The output signals of the delay elements Dm and Dm+1 in the delay line 152 of the delay locked loop 151 are provided to the multiplexing unit 193 as the preliminary write data strobe signals WDQS_PRE_TM and WDQSB_PRE_TM for the test mode.

Since the test mode signal TM is in the activated state, the preliminary write data strobe signals WDQS_PRE_TM and WDQSB_PRE_TM for the test mode are selected by the multiplexing unit 193 and provided to the data storage and input/output block 211 as the internal write data strobe signals WDQSi and WDQSBi.

The data storage and input/output block 211 writes data provided from the test device to the memory cell area by using the internal write data strobe signals WDQSi and WDQSBi, and outputs the written data to the test device by using the DLL clock signals RCLKDLL and FCLKDLL according to the read command of the test device.

Consequently, when testing the operation of the semiconductor integrated circuit 102 according to this embodiment, it is unnecessary to provide the write data strobe signal WDQS, and thus, the number of channels necessary for the test operation may be reduced.

Meanwhile, in the normal mode, the test mode signal TM is deactivated.

The write data strobe signal WDQS is provided as the preliminary write data strobe signals WDQS_PRE_NRM and WDQSB_PRE_NRM for the normal mode to the data storage and input/output block 211 through the buffer 141 and the phase separation unit 161.

Since the test mode signal TM is in the deactivated state, the preliminary write data strobe signals WDQS_PRE_NRM and WDQSB_PRE_NRM for the normal mode are selected by the multiplexing unit 193 and provided to the data storage and input/output block 211 as the internal write data strobe signal WDQSi.

The data storage and input/output block 211 writes data provided from the memory controller to the memory cell area by using the internal write data strobe signals WDQSi and WDQSBi according to the write command of the memory controller, e.g., a CPU or a GPU, and outputs the written data to the memory controller by using the DLL clock signals RCLKDLL and FCLKDLL according to the read command of the memory controller.

While certain embodiments have been described above, it will be understood to those skilled in the art that the embodiments described are by way of example only. Accordingly, a semiconductor integrated circuit described herein should not be limited based on the described embodiments. Rather, the semiconductor integrated circuit to described herein should only be limited in light of the claims that follow when taken in conjunction with the above description and accompanying drawings.

What is claimed is:

1. A semiconductor integrated circuit comprising:
a first pad;
a data storage and input/output block configured to store and output data by using a data strobe signal and a clock signal inputted through the first pad; and
a timing compensation unit configured to delay the clock signal to generate the data strobe signal.

2. The semiconductor integrated circuit according to claim 1, further comprising a second pad comprising a data strobe signal pad.

3. The semiconductor integrated circuit according to claim 2, further comprising a multiplexing unit configured to generate a selected signal by selecting one of the data strobe signal and a signal inputted through the second pad according to a test mode signal, and provide the selected signal to the data storage and input/output block.

4. The semiconductor integrated circuit according to claim 2, wherein the timing compensation unit is configured to generate the data strobe signal by delaying the clock signal by a set time corresponding to a signal delay from the second pad to the data storage and input/output block.

5. A semiconductor integrated circuit comprising:
a first pad;
a data storage and input/output block configured to store and output data by using a data strobe signal and a delay locked loop (DLL) clock signal;
a delay locked loop configured to generate the DLL clock signal by using a clock signal inputted through the first pad; and
a timing compensation unit configured to delay the DLL clock signal to generate the data strobe signal.

6. The semiconductor integrated circuit according to claim 5, further comprising a second pad comprising a data strobe signal pad.

7. The semiconductor integrated circuit according to claim 6, further comprising a multiplexing unit configured to generate a selected signal by selecting one of the data strobe signal and a signal inputted through the second pad according to a test mode signal, and provide the selected signal to the data storage and input/output block.

8. The semiconductor integrated circuit according to claim 6, wherein the timing compensation unit is configured to generate the data strobe signal by delaying the DLL clock signal by a set time corresponding to a signal delay from the second pad to the data storage and input/output block.

9. A semiconductor integrated circuit comprising:
a first pad;
a data storage and input/output block configured to store and output data by using a data strobe signal and a delay locked loop (DLL) clock signal; and
a delay locked loop configured to generate a received signal by receiving a clock signal through the first pad, and generate the DLL clock signal by delaying the received clock signal through a delay line including a plurality of delay elements,
wherein an output signal of a single delay element among the plurality of delay elements is generated as the data strobe signal.

10. The semiconductor integrated circuit according to claim 9, further comprising a second pad comprising a data strobe signal pad.

11. The semiconductor integrated circuit according to claim 10, wherein the output signal of the single delay element among the plurality of delay elements has a delay time corresponding to a timing offset between the DLL clock signal and a signal inputted through the second pad and transferred to the data storage and input/output block.

12. The semiconductor integrated circuit according to claim 10, further comprising a multiplexing unit configured to generate a selected signal by selecting one of the data strobe signal and a signal inputted through the second pad according to a test mode signal, and provide the selected signal to the data storage and input/output block.
